(19) United States
(12) Patent Application Publication
(10) Pub. No.: US 2026/0282207 A1
(43) Pub. Date: Sep. 17, 2026

(54) WIRING BOARD, ELECTRONIC DEVICE, AND ELECTRONIC MODULE

(71) Applicant: KYOCERA CORPORATION, Kyoto-shi, Kyoto (JP)

(72) Inventor: Shinichiro SAWA, Kyoto-shi, Kyoto (JP)

(73) Assignee: KYOCERA CORPORATION, Kyoto-shi, Kyoto (JP)

(21) Appl. No.: 19/469,201

(22) PCT Filed: Mar. 21, 2024
(86) PCT No.: PCT/JP2024/011018

§ 371 Date: Sep. 25, 2025

(30) Foreign Application Priority Data
Mar. 28, 2023 (JP) 2023-052256

(51) Int. Cl. H05K 1/02; H05K 1/11

(52) U.S. Cl. CPC H05K 1/0222; H05K 1/115

(57) ABSTRACT

A reflection loss of a high-frequency signal at a connection part between a signal wire and a signal through-hole conductor is reduced while a wiring board is miniaturized. Differential wiring includes a pair of signal wires located side by side between insulation layers adjacent to each other in a layering direction or on a first surface of an insulation substrate. A differential through-hole conductor includes a pair of signal through-hole conductors penetrating at least one of the plurality of insulation layers side by side. An outer diameter of a portion that is a part of the signal through-hole conductor and connects to a first end portion and/or a second end portion of each of the signal wires is smaller than an outer diameter of a portion continuous with the connecting portion.

### TECHNICAL FIELD

The present disclosure relates to a wiring board, an electronic device, and an electronic module.

### BACKGROUND

In a wiring board for mounting an electronic element such as a semiconductor element or an optical semiconductor element that operates at high speed, differential wiring and a differential through-hole conductor are used in order to efficiently propagate a high-speed and high-frequency signal. The differential wiring includes a pair of signal wires located side by side between insulation layers of an insulation substrate or on a first surface of the insulation substrate. The differential through-hole conductor includes a pair of signal through-hole conductors that penetrate at least one insulating layer of the insulation substrate side by side, and the signal through-hole conductor is electrically connected to the signal wire.

An end portion of the signal wire and an end portion of the signal through-hole conductor are connected in an L-shape, discontinuity of a transmission line occurs due to a sudden change in direction between the end portion of the signal wire and the end portion of the signal through-hole conductor, and reflection of the high-frequency signal occurs. The reflection loss of the high-frequency signal increases at a connection portion between the signal wire and the signal through-hole conductor, impairing the transmission property of the high-frequency signal and reducing the operability of an electronic element.

Therefore, a wiring board that can provide reduced reflection loss of a high-frequency signal at a connection portion between a signal wire and a signal through-hole conductor has been developed (see Patent Document 1). In the wiring board disclosed in Patent Document 1, a pair of signal wires (referred to as transmission line conductors in Patent Document 1) are connected to a pair of signal through-hole conductors via a pair of connection lines. The distance between the pair of connection lines gradually increases toward the signal through-hole conductor.

### CITATION LIST

### Patent Literature

Patent Document 1: JP 2008-311682 A

### SUMMARY

A wiring board according to the present disclosure includes: an insulation substrate formed by layering a plurality of insulation layers and having a first surface and a second surface on an opposite side of the first surface; differential wiring including a pair of signal wires located side by side between the plurality of insulation layers adjacent to each other in a layering direction or on the first surface; a differential through-hole conductor including a pair of signal through-hole conductors penetrating at least one of the plurality of insulation layers side by side, the signal through-hole conductor being electrically connected to the signal wires; ground wiring layers located between the plurality of insulation layers adjacent to each other in the layering direction and including an opening for allowing the differential through-hole conductor to pass therethrough; and a ground through-hole conductor penetrating at least one of the plurality of insulation layers and electrically connecting the ground wiring layers facing each other in the layering direction. An outer diameter of a connecting portion that is a part of the signal through-hole conductor and connects to a first end portion and/or a second end portion of each of the signal wires is smaller than an outer diameter of a continuous portion continuous with the connecting portion.

An electronic device according to the present disclosure includes the wiring board according to the present disclosure and an electronic element mounted on a side of a first surface of the wiring board.

An electronic module according to the present disclosure includes the electronic device according to the present disclosure and a module substrate on which the electronic device is mounted.

### BRIEF DESCRIPTION OF THE DRAWINGS

FIG. 1 is a schematic cross-sectional view of a wiring board according to a first embodiment of the present disclosure.

FIG. 2 is a schematic enlarged cross-sectional view taken along line II-II in FIG. 1.

FIG. 3 is a schematic enlarged cross-sectional view taken along line III-III in FIG. 1.

FIG. 4 is a schematic cross-sectional view of a wiring board according to another aspect of the first embodiment of the present disclosure.

FIG. 5 is a schematic cross-sectional view of a wiring board according to another aspect of the first embodiment of the present disclosure.

FIG. 6 is a schematic cross-sectional view of an electronic module according to the first embodiment of the present disclosure.

FIG. 7 is a schematic cross-sectional view of a wiring board according to a second embodiment of the present disclosure.

FIG. 8 is a schematic cross-sectional view of a wiring board according to a third embodiment of the present disclosure.

FIG. 9 is a schematic cross-sectional view of a wiring board according to a fourth embodiment of the present disclosure.

FIG. 10 is a schematic cross-sectional view of a wiring board according to a fifth embodiment of the present disclosure.

FIG. 11 is a diagram for explaining simulation models according to an example and a comparative example.

FIG. 12 is a graph showing a relationship between a frequency of a signal and a reflection loss of the signal, which is a result of simulation of signal transmission in the case of the example and the comparative example.

FIG. 13 is a graph showing a relationship between time and characteristic impedance, which is a result of simulation of signal transmission in the case of the example and the comparative example.

### DETAILED DESCRIPTION

In the wiring board disclosed in Patent Document 1, the reflection loss of the high-frequency signal at the connection portion between the signal wire and the signal through-hole conductor can be reduced, but the distance between the pair of connection lines gradually increases toward the signal through-hole conductor. As a result, the wiring board tends to expand in the direction of the distance between the pair of connection lines, in other words, in the direction in which the pair of signal wires are arranged. Therefore, reducing the reflection loss of the high-frequency signal at the connection portion between the signal wire and the signal through-hole conductor and improving the transmission property of the high-frequency signal while miniaturizing the wiring board is awaited.

The present disclosure can reduce the reflection loss of the high-frequency signal at the connection portion between the signal wire and the signal through-hole conductor and improve the transmission property of the high-frequency signal while miniaturizing the wiring board.

A wiring board, an electronic device, and an electronic module according to embodiments are described below in detail with reference to the drawings. Note that for convenience of description, each of the drawings referred to below is a simplified representation of only components necessary for description of the embodiments. Accordingly, the wiring board, the electronic device, and the electronic module according to the embodiments may include an optional component not illustrated in the referenced drawings. The dimensions of the components in the drawings may not faithfully represent the actual dimensions of the components, the dimension ratios of the members, or the like. Directions of the wiring board, the electronic device, and the electronic module are defined using an orthogonal coordinate system XYZ for convenience. A positive side in an X direction is defined as a right side, a negative side in the X direction is defined as a left side, a positive side in a Y direction is defined as a front side, a negative side in the Y direction is defined as a rear side, a positive side in a Z direction is defined as an upper side, and a negative side in the Z direction is defined as a lower side.

### First Embodiment

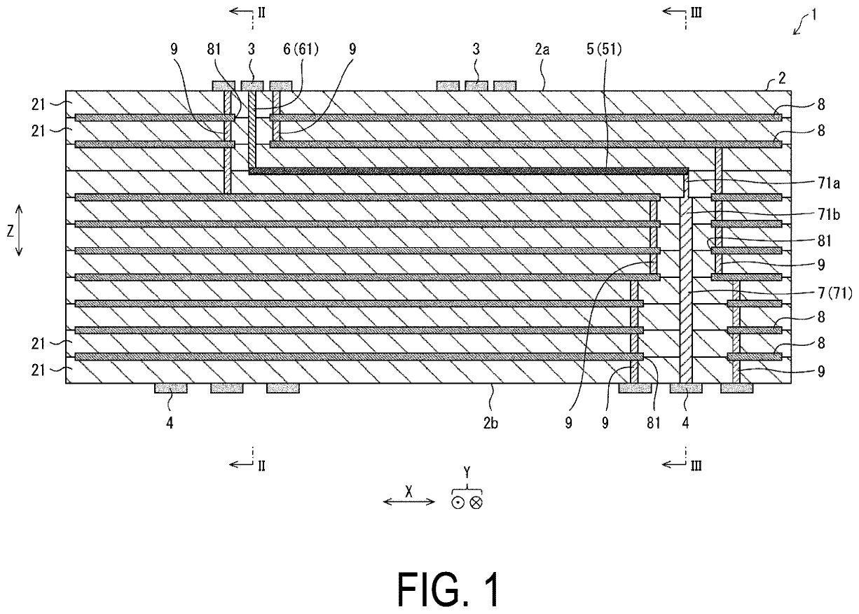

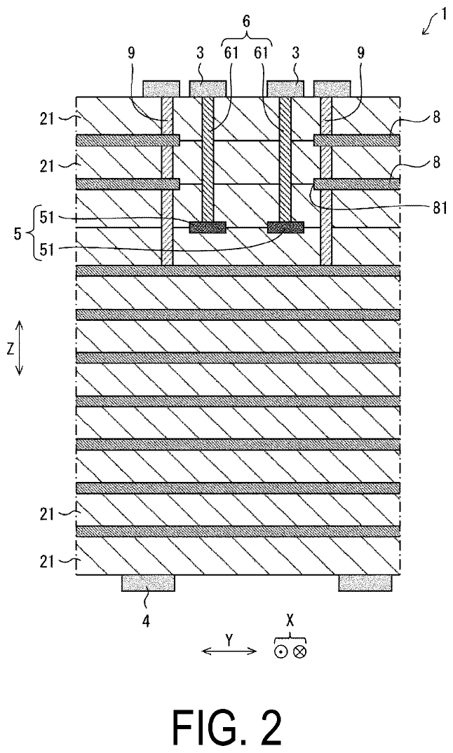

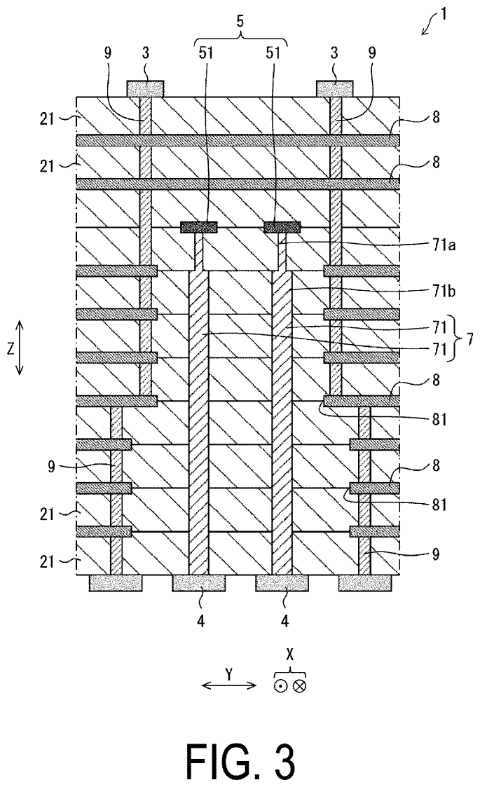

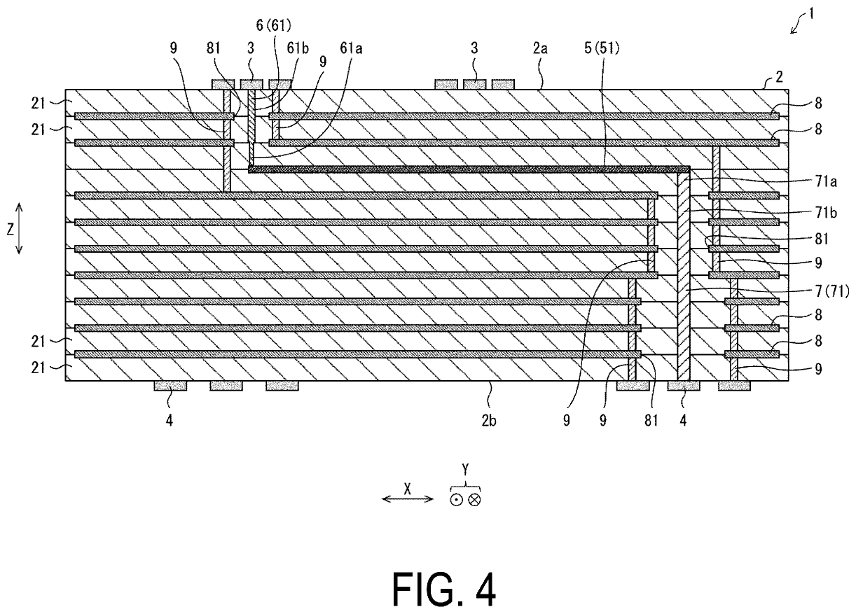

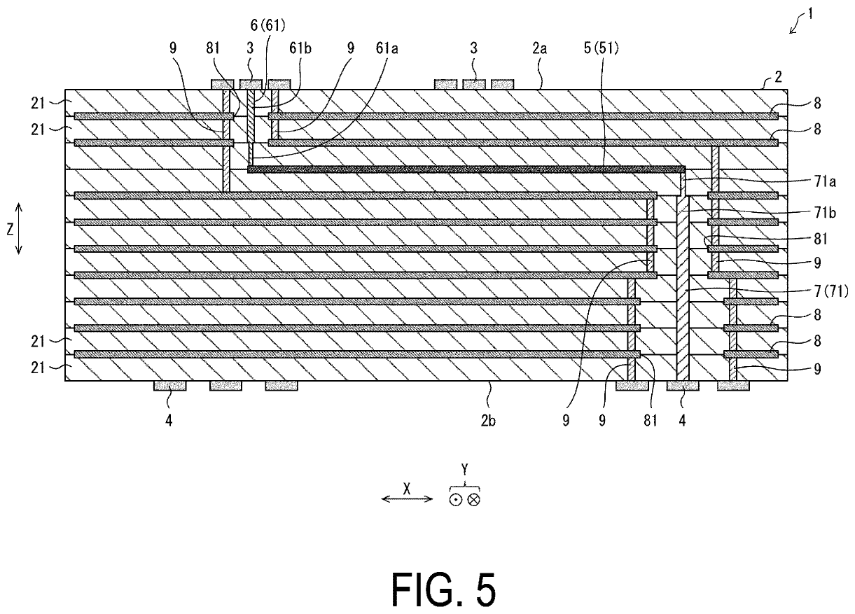

A wiring board 1 according to a first embodiment of the present disclosure is described with reference to FIGS. 1 to 5. FIG. 1 is a schematic cross-sectional view of the wiring board 1 according to the first embodiment of the present disclosure. FIG. 2 is a schematic enlarged cross-sectional view taken along line II-II in FIG. 1. FIG. 3 is a schematic enlarged cross-sectional view taken along line III-III in FIG. 1. FIGS. 4 and 5 are schematic cross-sectional views of the wiring board 1 according to another aspect of the first embodiment of the present disclosure.

As in the example illustrated in FIG. 1, the wiring board 1 according to the first embodiment of the present disclosure may include an insulation substrate 2 having a rectangular plate shape. The insulation substrate 2 may be formed by layering a plurality of insulation layers 21 having the same relative permittivity. The layering direction of the plurality of insulation layers 21 may be the Z direction. The insulation substrate 2 may have a first surface 2a and a second surface 2b located on an opposite side of the first surface 2a.

The wiring board 1 may include a plurality of electrode pads 3 as a plurality of electrodes located on the first surface 2a of the insulation substrate 2. The plurality of electrode pads 3 may be formed on the first surface 2a of the insulation substrate 2. In addition, the wiring board 1 may include a plurality of external electrodes 4 located on the second surface 2b of the insulation substrate 2. The plurality of external electrodes 4 may be formed on the second surface 2b of the insulation substrate 2.

As in the example illustrated in FIGS. 1 to 3, the wiring board 1 may include differential wiring 5 that transmits a signal (high-frequency signal), and the differential wiring 5 may be located between the plurality of insulation layers 21 adjacent to each other in the Z direction being the layering direction. The differential wiring 5 may include a pair of band-shaped signal wires 51 located in parallel between the insulation layers 21 adjacent to each other in the Z direction. The pair of signal wires 51 may be located on the first surface 2a of the insulation substrate 2. In the present specification, the description of “parallel” is intended to mean parallel at a visible level, and does not require being strictly parallel.

As in the example illustrated in FIGS. 1 and 2, the wiring board 1 may include a first differential through-hole conductor 6 located between the first surface 2a of the insulation substrate 2 and the differential wiring 5. The first differential through-hole conductor 6 may include a pair of first signal through-hole conductors 61 each having a columnar shape and penetrating at least one of the insulating layer 21 side by side. The first signal through-hole conductor 61 may be electrically connected to the signal wire 51. One end portion of the first signal through-hole conductor 61 may be connected to the electrode pad 3. The other end portion of the first signal through-hole conductor 61 may be connected to one end portion (first end portion) of the signal wire 51. When the pair of signal wires 51 are located on the first surface 2a of the insulation substrate 2, the first differential through-hole conductor 6 may be omitted from the wiring board 1.

As in the example illustrated in FIGS. 1 and 3, the wiring board 1 may include a second differential through-hole conductor 7 located between the differential wiring 5 and the second surface 2b of the insulation substrate 2. The second differential through-hole conductor 7 may include a pair of second signal through-hole conductors 71 each having a cylindrical shape and penetrating at least one of the insulation layers 21 side by side. The second signal through-hole conductor 71 may be electrically connected to the signal wire 51. One end portion of the second signal through-hole conductor 71 may be connected to the other end portion (second end portion) of the signal wire 51. The other end portion of the second signal through-hole conductor 71 may be connected to the external electrode 4.

That is, as in the example illustrated in FIG. 1, the electrode pad 3 and the external electrode 4 are electrically connected via the pair of first signal through-hole conductors 61, the pair of signal wires 51, and the pair of second signal through-hole conductors 71. A signal (high-frequency signal) can be transmitted between the electrode pad 3 and the external electrode 4 by the pair of first signal through-hole conductors 61, the pair of signal wires 51, and the pair of second signal through-hole conductors 71. The first differential through-hole conductor 6 and the second differential through-hole conductor 7 correspond to a differential through-hole conductor described in the appended claims of the present application. The first signal through-hole conductor 61 and the second signal through-hole conductor 71 correspond to a signal through-hole conductor described in the appended claims of the present application.

As in the example illustrated in FIG. 1, the wiring board 1 may include a plurality of ground wiring layers 8 located between the plurality of insulation layers 21 adjacent to each other in the Z direction being the layering direction. A pair of ground wiring layers 8 among the plurality of ground wiring layers 8 may face each other in the Z direction with the differential wiring 5 interposed therebetween. The pair of ground wiring layers 8 face each other in the Z direction with the differential wiring 5 interposed therebetween, so that the differential wiring 5 and the pair of ground wiring layers 8 form a strip line. The plurality of ground wiring layers 8 may have circular openings 81 for allowing the first differential through-hole conductor 6 or the second differential through-hole conductor 7 to pass therethrough. The inner peripheral surfaces of the openings 81 of the plurality of ground wiring layers 8 may be separated from the first differential through-hole conductor 6 or the second differential through-hole conductor 7. Since the plurality of ground wiring layers 8 have the openings 81, the differential wiring 5 and the plurality of ground wiring layers 8 can be electrically insulated from each other by the plurality of insulation layers 21.

As in the example illustrated in FIGS. 1 to 3, the wiring board 1 may include a plurality of ground through-hole conductors 9 each having a cylindrical shape and penetrating at least one of the insulation layers 21. The plurality of ground through-hole conductors 9 may electrically connect the ground wiring layers 8 facing each other in the Z direction being the layering direction. Any of the plurality of ground through-hole conductors 9 may surround the first differential through-hole conductor 6. Any of the plurality of ground through-hole conductors 9 may surround the second differential through-hole conductor 7.

A characteristic impedance of the differential wiring 5 is set by defining a width of the signal wire 51, a thickness of the insulating layer 21, and the like. A characteristic impedance of the first differential through-hole conductor 6 is set by defining an outer diameter of the first signal through-hole conductor 61, the thickness of the insulating layer 21, the size (inner diameter) of the opening 81 of the ground wiring layer 8, and the like. A characteristic impedance of the second differential through-hole conductor 7 is set by defining an outer diameter of the second signal through-hole conductor 71, the thickness of the insulating layer 21, the size (inner diameter) of the opening 81 of the ground wiring layer 8, and the like.

As in the example illustrated in FIGS. 1 and 3, an outer diameter of a connecting portion 71a that is a part of the second signal through-hole conductor 71 and connects to the second end portion of the signal wire 51 may be smaller than an outer diameter of a continuous portion 71b continuous with the connecting portion 71a. The connecting portion 71a of the second signal through-hole conductor 71 may be located concentrically with the continuous portion 71b. The length of the connecting portion 71a of the second signal through-hole conductor 71 is set to, for example, 0.1 mm or less. The outer diameter of the connecting portion 71a of the second signal through-hole conductor 71 is set to, for example, 50 μm or more and less than 75 μm. The outer diameter of the continuous portion 71b of the second signal through-hole conductor 71 is set to, for example, 75 μm.

The outer diameter of the first signal through-hole conductor 61 may be smaller than the outer diameter of the continuous portion 71b of the second signal through-hole conductor 71. The outer diameter of the first signal through-hole conductor 61 is set to, for example, 50 μm. The first signal through-hole conductor 61 corresponds to a portion that is a part of the signal through-hole conductor and connects to the first surface 2a side of the insulation substrate 2. The continuous portion 71b of the second signal through-hole conductor 71 corresponds to a portion that is a part of the signal through-hole conductor and connects to the second surface 2b side of the insulation substrate 2.

Instead of making the outer diameter of the connecting portion 71a of the second signal through-hole conductor 71 smaller than the outer diameter of the continuous portion 71b, the following configuration may be adopted.

As in the example illustrated in FIG. 4, the outer diameter of a connecting portion 61a that is a part of the first signal through-hole conductors 61 and connects to the first end portion of the signal wire 51 may be smaller than the outer diameter of a continuous portion 61b continuous with the connecting portion 61a. The connecting portion 61a of the first signal through-hole conductor 61 may be located concentrically with the continuous portion 61b. The length of the connecting portion 61 a of the first signal through-hole conductor 61 is set to, for example, 0.1 mm or less. The outer diameter of the connecting portion 61a of the first signal through-hole conductor 61 is set to, for example, 25 μm or more and less than 50 μm. The outer diameter of the continuous portion 61 b of the first signal through-hole conductor 61 is set to, for example, 50 μm.

In this case, the outer diameter of the continuous portion 61b of the first signal through-hole conductor 61 may be smaller than the outer diameter of the second signal through-hole conductor 71. The continuous portion 61b of the first signal through-hole conductor 61 corresponds to a portion that is a part of the signal through-hole conductor and connects to the first surface 2a side of the insulation substrate 2. The second signal through-hole conductor 71 correspond to a portion that is a part of the signal through-hole conductor and connects to the second surface 2b side of the insulation substrate 2.

As in the example illustrated in FIG. 5, the outer diameter of the connecting portion 61a of the first signal through-hole conductor 61 may be made smaller than the outer diameter of the continuous portion 61b, and the outer diameter of the connecting portion 71a of the second signal through-hole conductor 71 may be made smaller than the outer diameter of the continuous portion 71b. The connecting portion 61a of the first signal through-hole conductor 61 may be located concentrically with the continuous portion 61b. The connecting portion 71a of the second signal through-hole conductor 71 may be located concentrically with the continuous portion 71b.

The length of the connecting portion 61a of the first signal through-hole conductor 61 is set to, for example, 0.1 mm or less. The outer diameter of the connecting portion 61a of the first signal through-hole conductor 61 is set to, for example, 25 μm or more and less than 50 μm. The outer diameter of the continuous portion 61b of the first signal through-hole conductor 61 is set to, for example, 50 μm. The length of the connecting portion 71a of the second signal through-hole conductor 71 is set to, for example, 0.1 mm or less. The outer diameter of the connecting portion 71a of the second signal through-hole conductor 71 is set to, for example, 50 μm or more and less than 75 μm. The outer diameter of the continuous portion 71b of the second signal through-hole conductor 71 is set to, for example, 75 μm.

In this case, the outer diameter of the continuous portion 61b of the first signal through-hole conductor 61 may be smaller than the outer diameter of the continuous portion 71b of the second signal through-hole conductor 71. The continuous portion 61b of the first signal through-hole conductor 61 corresponds to a first portion that is a part of the signal through-hole conductor and connects to the first surface 2a side of the insulation substrate 2. The continuous portion 71b of the second signal through-hole conductor 71 corresponds to a second portion that is a part of the signal through-hole conductor and connects to the second surface 2b side of the insulation substrate 2.

In the wiring board 1, the insulation substrate 2 is formed by, for example, a ceramic green sheet lamination method. In this case, the insulation substrate 2 is made of, for example, a ceramic material such as an aluminum oxide sintered body, an aluminum nitride sintered body, a silicon carbide sintered body, a silicon nitride sintered body, a mullite sintered body, or a glass ceramic. The insulation substrate 2 may also be made of an organic insulating material such as polyimide, epoxy resin, fluororesin, polynorbornene, or benzocyclobutene.

When the insulation substrate 2 is made of, for example, an aluminum oxide sintered body, the wiring board 1 is produced as follows. First, an appropriate organic binder, a solvent, and the like are added to and mixed with a raw material powder such as aluminum oxide, silicon oxide, calcium oxide, or magnesium oxide to produce a slurry. A ceramic green sheet for the insulating layer 21 is produced by forming the slurry into a sheet shape by a doctor blade method, a calendar roll method, or the like. Subsequently, through holes for the first signal through-hole conductors 61, through holes for the second signal through-hole conductors 71, and through holes for the ground through-hole conductors 9 are formed in the ceramic green sheet by punching with a die or laser processing, and these through holes are filled with a metal paste obtained by adding and mixing metal powder, an appropriate organic binder, a solvent, and the like. Subsequently, a metal paste is applied by printing on the surface of the ceramic green sheet in a pattern corresponding to the electrode pad 3, the external electrode 4, the signal wire 51, and the ground wiring layer 8. Subsequently, the metal paste is fired together with the ceramic green sheet, so that the wiring board 1 can be produced.

When the insulation substrate 2 is made of, for example, an epoxy resin, the wiring board 1 is manufactured as follows. The insulating layer 21 having a through hole is formed by using a photosensitive resin, a mask having a predetermined pattern shape is formed on the insulating layer 21, and a metal thin film having a predetermined shape is formed in the through hole and on the surface of the insulating layer 21 by a sputtering method, a vacuum deposition method, or a plating method. Alternatively, the metal thin film may be formed on an entire upper surface of the insulating layer 21 without forming a mask, and then a mask having a predetermined shape may be formed, and unnecessary portions may be removed by etching. Alternatively, for example, the electrode pad 3, the external electrode 4, the signal wire 51, and the ground wiring layer 8 may be formed by processing a metal foil made of copper into a predetermined shape and transferring the metal foil onto the insulating layer 21. The first signal through-hole conductor 61, the second signal through-hole conductor 71, and the ground through-hole conductor 9 may be formed by filling a metal paste including a metal powder and a binder in the through holes.

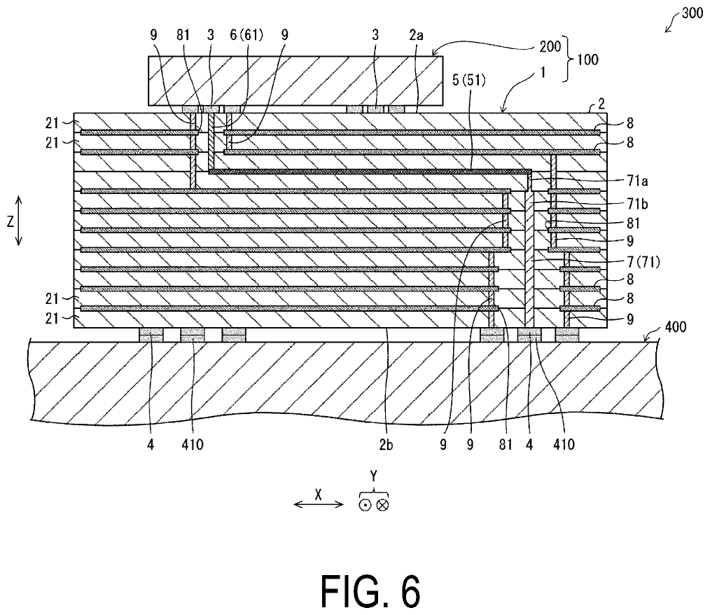

An electronic device 100 according to the first embodiment of the present disclosure and an electronic module 300 according to the first embodiment of the present disclosure are described with reference to FIG. 6. FIG. 6 is a schematic cross-sectional view of the electronic module 300 according to the first embodiment of the present disclosure.

As in the example illustrated in FIG. 6, the electronic device 100 according to the first embodiment of the present disclosure may include the wiring board 1 and an electronic element 200 mounted on the first surface 2a side of the insulation substrate 2 of the wiring board 1. The electronic element 200 may be, for example, a semiconductor element such as an integrated circuit (IC) or a large-scale integrated circuit (LSI). The electronic element 200 may be, for example, an optical semiconductor element such as a semiconductor laser (LD) or a photodiode (PD). A plurality of electrodes of the electronic device 100 may be electrically connected to the corresponding electrode pads 3 via solder such as a tin-lead (Sn—Pb) alloy or conductor bumps made of gold (Au) or the like.

As in the example illustrated in FIG. 6, the electronic module 300 according to the first embodiment of the present disclosure may include the electronic device 100 and a module substrate 400 on which the electronic device 100 is mounted. The plurality of external electrodes 4 of the wiring board 1 may be electrically connected to corresponding electrodes 410 of the module substrate 400 by solder or the like. The plurality of external electrodes 4 of the wiring board 1 are electrically connected to the corresponding electrodes 410 of the module substrate 400, so that signals can be input and output to/from the electronic element 200 and power can be supplied to the electronic element 200.

As in the example illustrated in FIGS. 1 and 3, the outer diameter of the connecting portion 71a of the second signal through-hole conductor 71 is smaller than the outer diameter of the continuous portion 71b. Therefore, the capacitance between the connecting portion 71a of the second signal through-hole conductor 71 and the ground through-hole conductor 9 can be reduced. This can reduce the reflection loss of a high-frequency signal at the connection portion between the signal wire 51 and the second signal through-hole conductor 71 without expanding the wiring board 1 in the Y direction that is the direction in which the pair of signal wires 51 are arranged.

As in the example illustrated in FIG. 4, the outer diameter of the connecting portion 61a of the first signal through-hole conductor 61 is smaller than the outer diameter of the continuous portion 61b. Therefore, the capacitance between the connecting portion 61a of the first signal through-hole conductor 61 and the ground through-hole conductor 9 can be reduced. This can reduce the reflection loss of the high-frequency signal at the connection portion between the signal wire 51 and the first signal through-hole conductor 61 without expanding the wiring board 1 in the Y direction that is the direction in which the pair of signal wires 51 are arranged.

Accordingly, the wiring board 1 of the first embodiment of the present disclosure can reduce the reflection loss of the high-frequency signal at the connection portion between the signal wire 51 and the second signal through-hole conductor 71 or the first signal through-hole conductor 61 and improve the transmission property of the high-frequency signal while miniaturizing the wiring board 1.

In particular, as in the example illustrated in FIG. 5, when the outer diameter of the connecting portion 61a of the first signal through-hole conductor 61 is smaller than the outer diameter of the continuous portion 61b and the outer diameter of the connecting portion 71a of the second signal through-hole conductor 71 is smaller than the outer diameter of the continuous portion 71b, the transmission property of a high-frequency signal can be further improved.

When the outer diameter of the first portion of the signal through-hole conductor connecting to the first surface 2a side of the insulation substrate 2 is smaller than the outer diameter of the second portion connecting to the second surface 2b side of the insulation substrate 2, the electronic element 200 can be mounted on the first surface 2a of the insulation substrate 2 at high density.

### Second Embodiment

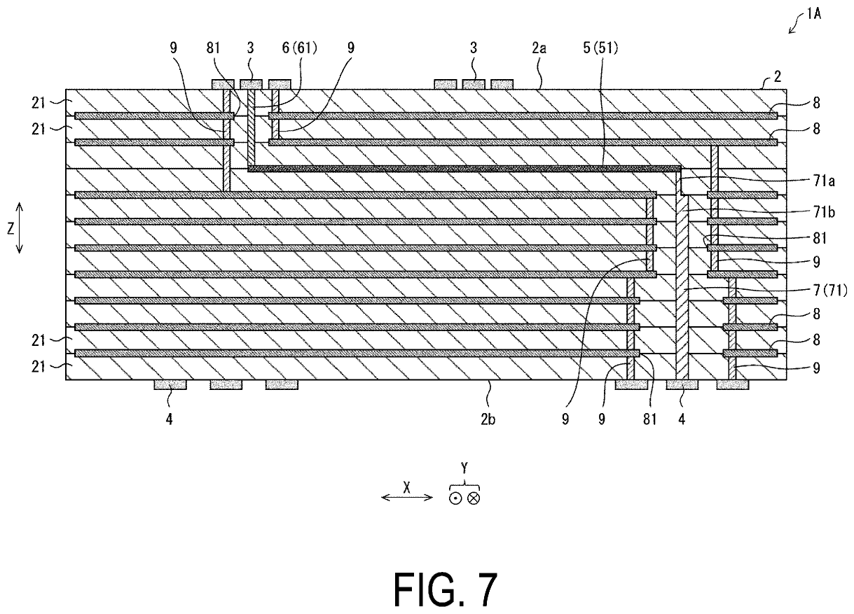

A wiring board 1A according to a second embodiment of the present disclosure is described with reference to FIG. 7. FIG. 7 is a schematic cross-sectional view of the wiring board 1A according to the second embodiment of the present disclosure.

As in the example illustrated in FIG. 7, the wiring board 1A according to the second embodiment of the present disclosure has the same configuration as the wiring board 1 according to the first embodiment of the present disclosure except for a part of the configuration. Among the configurations of the wiring board 1A, a configuration different from the configuration of the wiring board 1 according to the first embodiment is described. For convenience of description, members having the same functions as the members described in the first embodiment are denoted by the same reference signs.

The connecting portion 71a of the second signal through-hole conductor 71 may be eccentric to an axial center of the continuous portion 71b. The connecting portion 71a of the second signal through-hole conductor 71 may be eccentric toward the negative side in the X direction, in other words, toward the center of the insulation substrate 2. The connecting portion 71a of the second signal through-hole conductor 71 may be eccentric toward the positive side in the X direction or in the Y direction. The amount of eccentricity of the connecting portion 71a of the second signal through-hole conductor 71 may be equal to or less than half of the outer diameter of the continuous portion 71b of the second signal through-hole conductor 71.

Also in the wiring board 1A according to the second embodiment of the present disclosure, instead of making the outer diameter of the connecting portion 71a of the second signal through-hole conductor 71 smaller than the outer diameter of the continuous portion 71b, the outer diameter of the connecting portion 61a of the first signal through-hole conductor 61 may be made smaller than the outer diameter of the continuous portion 61b (see FIG. 4). The outer diameter of the connecting portion 61a of the first signal through-hole conductor 61 may be made smaller than the outer diameter of the continuous portion 61b, and the outer diameter of the connecting portion 71a of the second signal through-hole conductor 71 may be made smaller than the outer diameter of the continuous portion 71b (see FIG. 5). In these cases, the connecting portion 61a of the first signal through-hole conductor 61 may be eccentric to an axial center of the continuous portion 61b.

As in the example illustrated in FIG. 7, when the connecting portion 71a of the second signal through-hole conductor 71 is eccentric to the axial center of the continuous portion 71b, the capacitance between the connecting portion 71a of the second signal through-hole conductor 71 and the ground through-hole conductor 9 can be further reduced. Alternatively, when the connecting portion 61a of the first signal through-hole conductor 61 is eccentric to the axial center of the continuous portion 61b, the capacitance between the connecting portion 61a of the first signal through-hole conductor 61 and the ground through-hole conductor 9 can be further reduced. This can sufficiently reduce the reflection loss of the high-frequency signal at the connection portion between the signal wire 51 and the second signal through-hole conductor 71 or the first signal through-hole conductor 61 and further improve the transmission property of the high-frequency signal.

### Third Embodiment

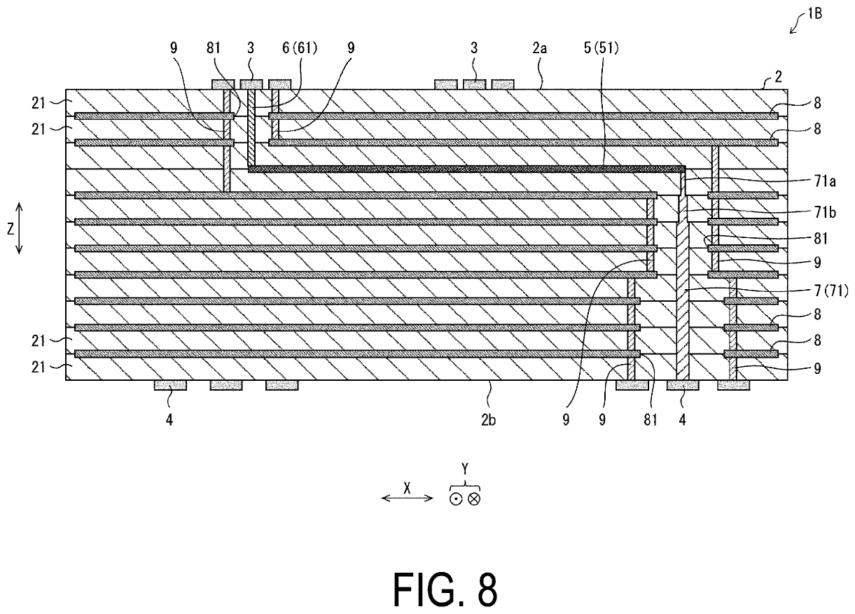

A wiring board 1B according to a third embodiment of the present disclosure is described with reference to FIG. 8. FIG. 8 is a schematic cross-sectional view of the wiring board 1B according to the third embodiment of the present disclosure.

As in the example illustrated in FIG. 8, the wiring board 1B according to the third embodiment of the present disclosure has the same configuration as the wiring board 1 according to the first embodiment of the present disclosure except for a part of the configuration. Among the configurations of the wiring board 1B, a configuration different from the configuration of the wiring board 1 according to the first embodiment is described. For convenience of description, members having the same functions as the members described in the first embodiment are denoted by the same reference signs.

The connecting portion 71a of the second signal through-hole conductor 71 may be enlarged in diameter in at least two stages toward the continuous portion 71b. The length of the connecting portion 71 a of the second signal through-hole conductor 71 is set to, for example, 0.1 mm or less. The maximum outer diameter of the connecting portion 71a of the second signal through-hole conductor 71 is set to, for example, 50 μm or more and less than 75 μm. The outer diameter of the continuous portion 71b of the second signal through-hole conductor 71 is set to, for example, 75 μm.

Also in the wiring board 1B according to the third embodiment of the present disclosure, instead of making the outer diameter of the connecting portion 71a of the second signal through-hole conductor 71 smaller than the outer diameter of the continuous portion 71b, the outer diameter of the connecting portion 61a of the first signal through-hole conductor 61 may be made smaller than the outer diameter of the continuous portion 61b (see FIG. 4). The outer diameter of the connecting portion 61a of the first signal through-hole conductor 61 may be made smaller than the outer diameter of the continuous portion 61b, and the outer diameter of the connecting portion 71a of the second signal through-hole conductor 71 may be made smaller than the outer diameter of the continuous portion 71b (see FIG. 5). In these cases, the connecting portion 61a of the first signal through-hole conductor 61 may be enlarged in diameter in at least two stages toward the continuous portion 61b. The length of the connecting portion 61a of the first signal through-hole conductor 61 is set to, for example, 0.1 mm or less. The maximum outer diameter of the connecting portion 61a of the first signal through-hole conductor 61 is set to, for example, 25 μm or more and less than 50 μm. The outer diameter of the continuous portion 61b of the first signal through-hole conductor 61 is set to, for example, 50 μm.

As in the example illustrated in FIG. 8, when the connecting portion 71a of the second signal through-hole conductor 71 is enlarged in diameter in at least two stages toward the continuous portion 71b, changes in specific impedance can be made gentle at the connection portion between the signal wire 51 and the second signal through-hole conductor 71. Alternatively, when the connecting portion 61a of the first signal through-hole conductor 61 is enlarged in diameter in at least two stages toward the continuous portion 61b, changes in specific impedance can be made gentle at the connection portion between the signal wire 51 and the first signal through-hole conductor 61. This can sufficiently reduce the reflection loss of the high-frequency signal at the connection portion between the signal wire 51 and the second signal through-hole conductor 71 or the first signal through-hole conductor 61 and further improve the transmission property of the high-frequency signal.

### Fourth Embodiment

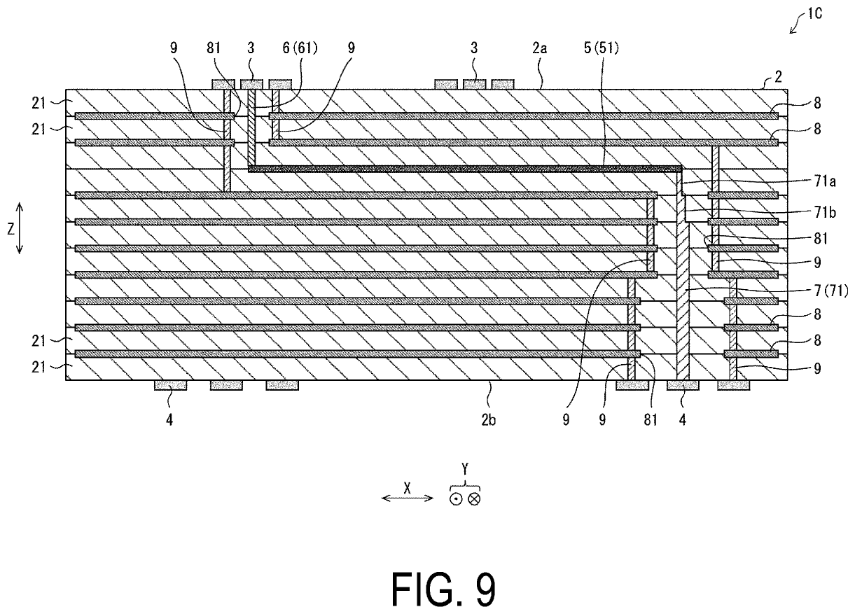

A wiring board 1C according to a fourth embodiment of the present disclosure is described with reference to FIG. 9. FIG. 9 is a schematic cross-sectional view of the wiring board 1C according to the fourth embodiment of the present disclosure.

As in the example illustrated in FIG. 9, the wiring board 1C according to the fourth embodiment of the present disclosure has the same configuration as the wiring board 1B according to the third embodiment except for a part of the configuration. Among the configurations of the wiring board 1C, a configuration different from the configuration of the wiring board 1B according to the third embodiment is described. For convenience of description, members having the same function as the members described in the third embodiment are denoted by the same reference signs.

The connecting portion 71a of the second signal through-hole conductor 71 may be eccentric to the axial center of the continuous portion 71b. The connecting portion 71a of the second signal through-hole conductor 71 may be eccentric toward the negative side in the X direction, in other words, toward the center of the insulation substrate 2. The connecting portion 71a of the second signal through-hole conductor 71 may be eccentric toward the positive side in the X direction or in the Y direction. The maximum amount of eccentricity of the connecting portion 71a of the second signal through-hole conductor 71 may be equal to or less than half of the outer diameter of the continuous portion 71b of the second signal through-hole conductor 71.

Also in the wiring board 1C according to the fourth embodiment of the present disclosure, instead of making the outer diameter of the connecting portion 71a of the second signal through-hole conductor 71 smaller than the outer diameter of the continuous portion 71b, the outer diameter of the connecting portion 61a of the first signal through-hole conductor 61 may be made smaller than the outer diameter of the continuous portion 61b (see FIG. 4). The outer diameter of the connecting portion 61a of the first signal through-hole conductor 61 may be made smaller than the outer diameter of the continuous portion 61b, and the outer diameter of the connecting portion 71a of the second signal through-hole conductor 71 may be made smaller than the outer diameter of the continuous portion 71b (see FIG. 5).

As in the example illustrated in FIG. 9, when the connecting portion 71a of the second signal through-hole conductor 71 is eccentric to the axial center of the continuous portion 71b, the capacitance between the connecting portion 71a of the second signal through-hole conductor 71 and the ground through-hole conductor 9 can be further reduced. Alternatively, when the connecting portion 61a of the first signal through-hole conductor 61 is eccentric to the axial center of the continuous portion 61b, the capacitance between the connecting portion 61a of the first signal through-hole conductor 61 and the ground through-hole conductor 9 can be further reduced. This can more sufficiently reduce the reflection loss of the high-frequency signal at the connection portion between the signal wire 51 and the second signal through-hole conductor 71 or the first signal through-hole conductor 61 and further improve the transmission property of the high-frequency signal.

### Fifth Embodiment

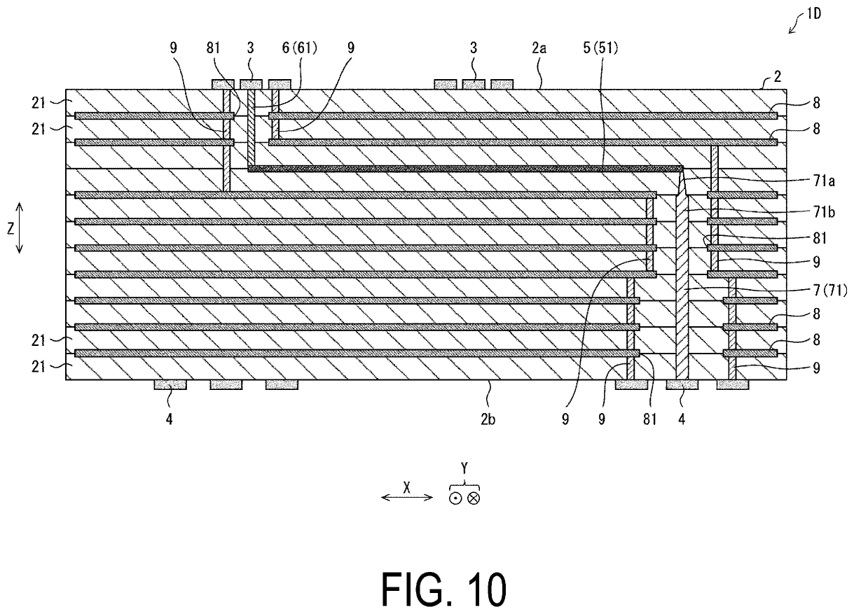

A wiring board 1D according to a fifth embodiment of the present disclosure is described with reference to FIG. 10. FIG. 10 is a cross-sectional view of the wiring board 1D according to the fifth embodiment of the present disclosure.

As in the example illustrated in FIG. 10, the wiring board 1D according to the fifth embodiment of the present disclosure has the same configuration as the wiring board 1 according to the first embodiment of the present disclosure except for a part of the configuration. Among the configurations of the wiring board 1D, a configuration different from the configuration of the wiring board 1 according to the first embodiment is described. For convenience of description, members having the same functions as the members described in the first embodiment are denoted by the same reference signs.

The connecting portion 71a of the second signal through-hole conductor 71 may be enlarged in diameter in a tapered shape toward the continuous portion 71b. The shape of the connecting portion 71a of the second signal through-hole conductor 71 is tapered, but is not limited to a strictly tapered shape. Even when the connecting portion 71a of the second signal through-hole conductor 71 has a step due to the layering deviation of the insulation layers 21, the connecting portion 71a of the second signal through-hole conductor 71 can be sufficiently visually recognized as being tapered as a whole. The length of the connecting portion 71a of the second signal through-hole conductor 71 is set to, for example, 0.1 mm or less. The maximum outer diameter of the connecting portion 71a of the second signal through-hole conductor 71 is set to, for example, 50 μm or more and less than 75 μm. The outer diameter of the continuous portion 71b of the second signal through-hole conductor 71 is set to, for example, 75 μm.

Also in the wiring board 1D according to the fifth embodiment of the present disclosure, instead of making the outer diameter of the connecting portion 71a of the second signal through-hole conductor 71 smaller than the outer diameter of the continuous portion 71b, the outer diameter of the connecting portion 61a of the first signal through-hole conductor 61 may be made smaller than the outer diameter of the continuous portion 61b (see FIG. 4). The outer diameter of the connecting portion 61a of the first signal through-hole conductor 61 may be made smaller than the outer diameter of the continuous portion 61b, and the outer diameter of the connecting portion 71a of the second signal through-hole conductor 71 may be made smaller than the outer diameter of the continuous portion 71b (see FIG. 5). In these cases, the connecting portion 61a of the first signal through-hole conductor 61 may be enlarged in diameter in a tapered shape toward the continuous portion 61b. The length of the connecting portion 61a of the first signal through-hole conductor 61 is set to, for example, 0.1 mm or less. The maximum outer diameter of the connecting portion 61a of the first signal through-hole conductor 61 is set to, for example, 25 μm or more and less than 50 μm. The outer diameter of the continuous portion 61b of the first signal through-hole conductor 61 is set to, for example, 50 μm.

As in the example illustrated in FIG. 10, when the connecting portion 71a of the second signal through-hole conductor 71 is enlarged in diameter in a tapered shape toward the continuous portion 71b, changes in specific impedance can be made gentle at the connection portion between the signal wire 51 and the second signal through-hole conductor 71. Alternatively, when the connecting portion 61a of the first signal through-hole conductor 61 is enlarged in diameter in a tapered shape toward the continuous portion 61b, changes in specific impedance can be made gentle at the connection portion between the signal wire 51 and the first signal through-hole conductor 61. This can sufficiently reduce the reflection loss of the high-frequency signal at the connection portion between the signal wire 51 and the second signal through-hole conductor 71 or the first signal through-hole conductor 61 and further improve the transmission property of the high-frequency signal.

In an embodiment, (1) a wiring board includes: an insulation substrate formed by layering a plurality of insulation layers and having a first surface and a second surface on an opposite side of the first surface; differential wiring including a pair of signal wires located side by side between the plurality of insulation layers adjacent to each other in a layering direction or on the first surface; a differential through-hole conductor including a pair of signal through-hole conductors penetrating at least one of the plurality of insulation layers side by side, the signal through-hole conductor being electrically connected to the signal wires; ground wiring layers located between the plurality of insulation layers adjacent to each other in the layering direction and including an opening for allowing the differential through-hole conductor to pass therethrough; and a ground through-hole conductor penetrating at least one of the plurality of insulation layers and electrically connecting the ground wiring layers facing each other in the layering direction. An outer diameter of a connecting portion that is a part of the signal through-hole conductor and connects to a first end portion and/or a second end portion of each of the signal wires is smaller than an outer diameter of a continuous portion continuous with the connecting portion.

(2) In the wiring board of (1), the differential wiring may be located between the plurality of insulation layers adjacent to each other in the layering direction, an outer diameter of a first portion that is a part of the signal through-hole conductor and connects to the first end portion of each of the signal wires may be smaller than an outer diameter of a portion continuous with the first portion, and an outer diameter of a second portion that is a part of the signal through-hole conductor and connects to the second end portion of each of the signal wires may be smaller than an outer diameter of a portion continuous with the second portion.

(3) In the wiring board of (1) or (2), the differential wiring may be located between the plurality of insulation layers adjacent to each other in the layering direction, and an outer diameter of a portion that is a part of the signal through-hole conductor and connects to a side of the first surface may be smaller than an outer diameter of a portion that is a part of the signal through-hole conductor and connects to a side of the second surface.

(4) In the wiring board of any one of (1) to (3), the connecting portion of the signal through-hole conductor may be eccentric to an axial center of the continuous portion.

(5) In the wiring board of any one of (1) to (4), the connecting portion of the signal through-hole conductor may be enlarged in diameter in at least two stages toward the continuous portion.

(6) In the wiring board of any one of (1) to (4), the connecting portion of the signal through-hole conductor may be enlarged in diameter in a tapered shape toward the continuous portion.

(7) An electronic device includes the wiring board of any one of (1) to (6), and an electronic element mounted on a side of a first surface of the wiring board.

(8) An electronic module includes the electronic device of (7) and a module substrate on which the electronic device is mounted.

### EXAMPLES

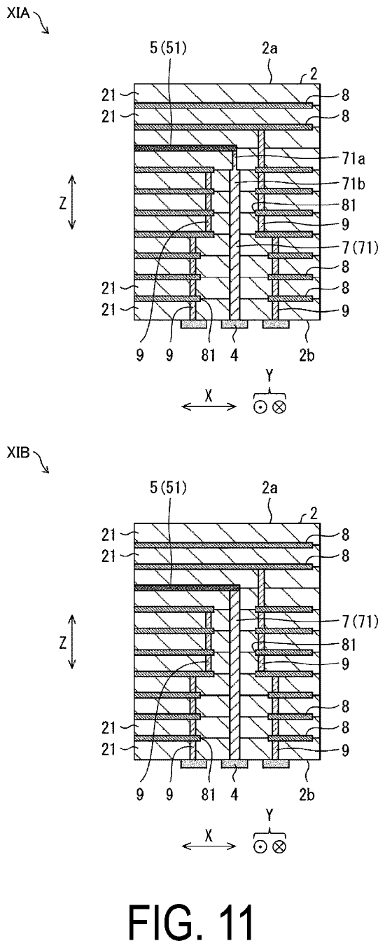

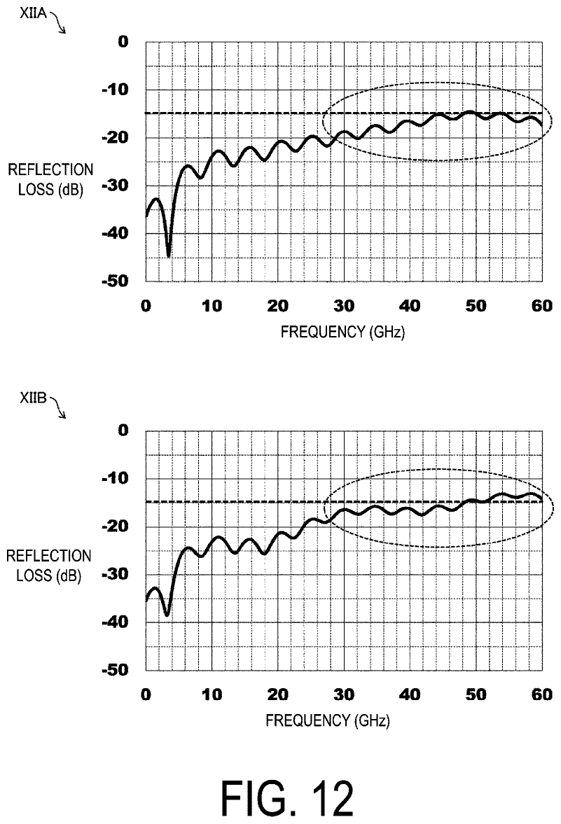

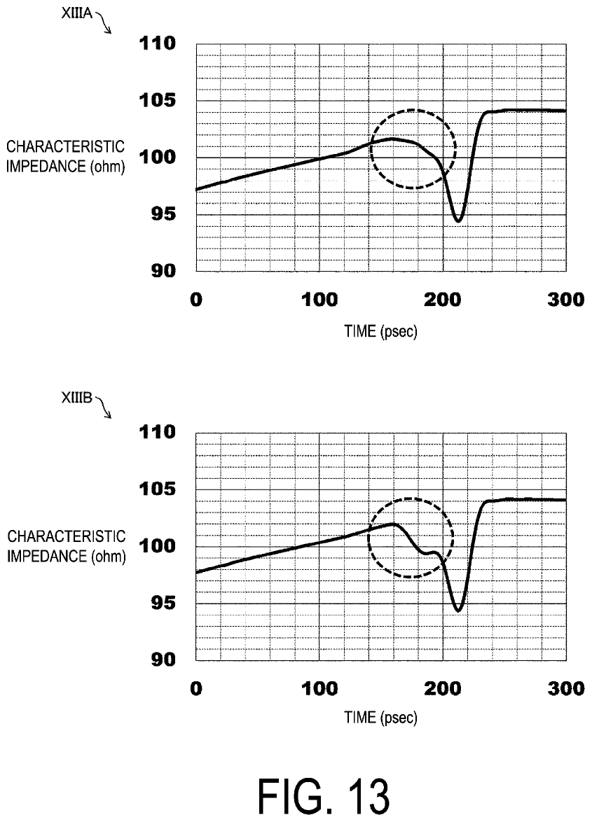

An example of the present disclosure is described with reference to FIGS. 11 to 13. XIA of FIG. 11 is a diagram for explaining a simulation model according to the example. XIB of FIG. 11 is a diagram for explaining a simulation model according to a comparative example. XIIA of FIG. 12 is a graph showing a relationship between a frequency of a signal and a reflection loss of the signal, which is a result of simulation of signal transmission in the case of the example. XIIB of FIG. 12 is a graph showing a relationship between a frequency of a signal and a reflection loss of the signal, which is a result of simulation of signal transmission in the case of the comparative example. XIIIA of FIG. 13 is a graph showing a relationship between time and characteristic impedance, which is a result of simulation of signal transmission in the case of the example. XIIIB of FIG. 13 is a graph showing a relationship between time and characteristic impedance, which is a result of simulation of signal transmission in the case of the comparative example.

As illustrated in the example of XIA in FIG. 11, the simulation model according to the example is obtained by modeling a part of the wiring board 1 (see FIG. 1) according to the first embodiment. In the simulation model according to the example, the width of the signal wire 51 was set to 51 μm, the outer diameter of the connecting portion 71a of the second signal through-hole conductor 71 was set to 50 μm, and the outer diameter of the continuous portion 71b of the second signal through-hole conductor 71 was set to 75 μm. In XIA of FIG. 11, the components of the simulation model according to the example are given the same reference signs as corresponding components of the wiring board 1 according to the first embodiment.

As illustrated in the example of XIB in FIG. 11, the simulation model according to the comparative example is different from the simulation model according to the example only in that the outer diameter of the second signal through-hole conductor 71 is set to be constant. In the simulation model according to the comparative example, the outer diameter of the second signal through-hole conductor 71 was set to 75 μm. In XIB of FIG. 11, the components of the simulation model according to the comparative example are given the same reference signs as corresponding components of the wiring board 1 according to the first embodiment.

As a result of the simulation of the signal transmission in the case of the example, the relationship between the frequency of the signal and the reflection loss of the signal is summarized as indicated by XIIA of FIG. 12. As a result of the simulation of the signal transmission in the case of the comparative example, the relationship between the frequency of the signal and the reflection loss of the signal is summarized as illustrated in XIIB of FIG. 12. That is, as indicated by XIIA and XIIB of FIG. 12, it was found that when the frequency of the signal exceeds 50 GHz, the reflection loss of the signal exceeds −15 dB in the case of the comparative example, whereas the reflection loss of the signal can be reduced to −15 dB or less in the case of the example.

As a result of the simulation of the signal transmission in the case of the example, the relationship between the time and the characteristic impedance is summarized as indicated by XIIIA of FIG. 13. As a result of the simulation of the signal transmission in the case of the comparative example, the relationship between the time and the characteristic impedance is summarized as indicated by XIIIB of FIG. 13. That is, as indicated by XIIIA and XIIIB of FIG. 13, it was found that when the time exceeds 160 psec, the characteristic impedance was significantly decreased in the case of the comparative example, whereas the characteristic impedance was gently decreased in the case of the example.

The invention according to the present disclosure has been described above based on various drawings and examples. However, the invention according to the present disclosure is not limited to the above-described embodiments. That is, the invention according to the present disclosure can be modified in various ways within the scope described in the present disclosure, and embodiments obtained by combining technical means disclosed in the different embodiments as appropriate are also included in the technical scope of the invention according to the present disclosure. In other words, it should be noted that a person skilled in the art can easily make various variations or modifications based on the present disclosure. It should also be noted that these variations or modifications are included in the scope of the present disclosure.

### REFERENCE SIGNS

1 Wiring board (wiring board according to first embodiment)
2 Insulation substrate
21 Insulation layer
3 Electrode pad (electrode)
4 External electrode
5 Differential wiring
51 Signal wire
6 First differential through-hole conductor (differential through-hole conductor)
61 First signal through-hole conductor (signal through-hole conductor)
61a Connecting portion
61b Continuous portion
7 Second differential through-hole conductor (differential through-hole conductor)
71 Second signal through-hole conductor (signal through-hole conductor)
71a Connecting portion
71b Continuous portion
8 Ground wiring layer
81 Opening portion
9 Ground through-hole conductor
100 Electronic device
200 Electronic element
300 Electronic module
400 Module substrate
410 Electrode
1A Wiring board (wiring board according to second embodiment)
1B Wiring board (wiring board according to third embodiment)
1C Wiring board (wiring board according to fourth embodiment)
1D Wiring board (wiring board according to fifth embodiment)

1. A wiring board, comprising:
an insulation substrate formed by layering a plurality of insulation layers and having a first surface and a second surface on an opposite side of the first surface;
differential wiring including a pair of signal wires located side by side between the plurality of insulation layers adjacent to each other in a layering direction or on the first surface;
a differential through-hole conductor comprising a pair of signal through-hole conductors penetrating at least one of the plurality of insulation layers side by side, the signal through-hole conductor being electrically connected to the signal wires;
ground wiring layers located between the plurality of insulation layers adjacent to each other in the layering direction and comprising an opening for allowing the differential through-hole conductor to pass therethrough; and
a ground through-hole conductor penetrating at least one of the plurality of insulation layers and electrically connecting the ground wiring layers facing each other in the layering direction, wherein
an outer diameter of a connecting portion that is a part of the signal through-hole conductor and connects to a first end portion and/or a second end portion of each of the signal wires is smaller than an outer diameter of a continuous portion continuous with the connecting portion.

2. The wiring board according to claim 1, wherein
the differential wiring is located between the plurality of insulation layers adjacent to each other in the layering direction,
an outer diameter of a first portion that is a part of the signal through-hole conductor and connects to the first end portion of each of the signal wires is smaller than an outer diameter of a portion continuous with the first portion, and
an outer diameter of a second portion that is a part of the signal through-hole conductor and connects to the second end portion of each of the signal wires is smaller than an outer diameter of a portion continuous with the second portion.

3. The wiring board according to claim 1, wherein
the differential wiring is located between the plurality of insulation layers adjacent to each other in the layering direction, and
an outer diameter of a portion that is a part of the signal through-hole conductor and connects to a side of the first surface is smaller than an outer diameter of a portion that is a part of the signal through-hole conductor and connects to a side of the second

4. The wiring board according to claim 1, wherein the connecting portion of the signal through-hole conductor is eccentric to an axial center of the continuous portion.

5. The wiring board according to claim 1, wherein the connecting portion of the signal through-hole conductor is enlarged in diameter in at least two stages toward the continuous portion.

6. The wiring board according to claim 1, wherein the connecting portion of the signal through-hole conductor is enlarged in diameter in a tapered shape toward the continuous portion.

7. An electronic device, comprising:
the wiring board according to claim 1; and
an electronic element mounted on a side of a first surface of the wiring board.

8. An electronic module, comprising:
the electronic device according to claim 7; and
a module substrate on which the electronic device is mounted.

9. The wiring board according to claim 2, wherein
the differential wiring is located between the plurality of insulation layers adjacent to each other in the layering direction, and
an outer diameter of a portion that is a part of the signal through-hole conductor and connects to a side of the first surface is smaller than an outer diameter of a portion that is a part of the signal through-hole conductor and connects to a side of the second surface.

10. The wiring board according to claim 2, wherein the connecting portion of the signal through-hole conductor is eccentric to an axial center of the continuous portion.

11. The wiring board according to claim 3, wherein the connecting portion of the signal through-hole conductor is eccentric to an axial center of the continuous portion.

12. The wiring board according to claim 9, wherein the connecting portion of the signal through-hole conductor is eccentric to an axial center of the continuous portion.
